(19) United States
(12) Patent Application Publication
(10) Pub. No.: US 2007/0292711 A1
(43) Pub. Date: Dec. 20, 2007

(54) Low Friction Sliding Mechanism

(75) Inventors: Takafumi Ueno, Yokohama (JP); Yutaka Mabuchi, Yokohama (JP); Makoto Kano, Yokohama (JP); Saburo Abe, Kanagawa (JP)

Correspondence Address: FOLEY AND LARDNER LLP;SUITE 500, 3000 K STREET NW, WASHINGTON, DC, 20007, US

(73) Assignee: Nissan Motor Co., Ltd., Yokohama-shi (JP)

(21) Appl. No.: 11/794,962

(22) PCT Filed: Jan. 5, 2006
(86) PCT No.: PCT/IB06/00008

§ 371 Date: Jul. 10, 2007

(30) Foreign Application Priority Data
Jan. 11, 2005 (JP) 2005-004397

(51) Int. Cl. C23C 16/26

(52) U.S. Cl. 428/688; 427/249.1

(57) ABSTRACT

A sliding mechanism includes a contact area between at least two sliding members. A low friction coating is applied on at least a portion of one of the at least two sliding members at the contact area. The low friction coating is a hard carbon including a diamond like carbon material selected from the group consisting of diamond, amorphous a-C diamond like carbon (DLC), and amorphous a-C:H DLC. A grease is applied on the low friction coating, wherein the grease comprises a base oil selected from the group consisting of ester oils, ether oils and combinations thereof.

This application claims priority from Japanese Patent Application No. 2005-004397, filed Jan. 11, 2005, the entire contents of which is incorporated herein by reference.

### TECHNICAL FIELD

The invention relates to low friction coatings that reduce friction between moving parts.

### BACKGROUND

In many industrial applications such as, for example, vehicular parts, machine tools, saws and the like, parts contact one another in a contact area that may be a point, a line, or a surface region. Low friction coatings and/or lubricating oils may be applied to the contact area to reduce the friction that occurs between the moving parts. The reduced coefficient of friction at the contact area improves efficiency, reduces wear, and decreases operational noise. If the parts are used in a vehicle such as an automobile, and in certain cases the use of low friction coatings may reduce fuel consumption.

Hard carbon materials, particularly DLC (Diamond-Like-Carbon) materials, have been used in low friction coatings to reduce the coefficient of friction between the contact areas of parts that move with respect to one another, referred to herein generally as sliding members or sliding parts. The DLC materials have a low coefficient of friction in air. However, the coefficient of friction of a particular coating material in air does not necessarily correlate with the coefficient of friction of that coating material in the presence of a lubricating oil or grease. Since sliding members typically operate with a thin layer of a lubricant in the contact area, it would be desirable to obtain a low friction hard carbon coating that provides a reduced coefficient of friction in the presence of such lubricants.

### SUMMARY

In one embodiment, a sliding mechanism includes a contact area between at least two sliding members. A low friction coating is applied on at least a portion of one of the at least two sliding members at the contact area. The low friction coating is a hard carbon film, which is a thin film, including a diamond like carbon material selected from the group consisting of diamond, amorphous a-C diamond like carbon (DLC), and amorphous a-C:H DLC. A grease is applied on the low friction coating, wherein the grease comprises a base oil selected from the group consisting of ester oils, ether oils and combinations thereof.

In another embodiment, a method includes forming a low friction coating on at least a portion of a sliding member. The low friction coating is a hard carbon film including a diamond like carbon material selected from the group consisting of diamond, amorphous a-C diamond like carbon (DLC), and amorphous a-C:H DLC. The method further includes adding a grease on the low friction coating, wherein the grease includes a base oil selected from the group consisting of ester oils, ether oils and combinations thereof.

In an additional embodiment, a sliding member includes a low friction coating on at least a portion thereof. The low friction coating is a thin film including an amorphous a-C:H diamond-like carbon, wherein the a-C:H in the thin film includes less than or equal to 20% by mass H.

In yet another embodiment, a sliding mechanism includes at least two sliding members. The sliding members include friction reducing means include a combination of a diamond like carbon film and a grease including at least one of an ester and an ether base oil.

The embodiments of the disclosure may provide one or more advantages. For example, application of a hard carbon film and a grease decreases wear to the sliding mechanism by reducing the coefficient of friction in contact areas between adjacent sliding members. The low frictional coefficient may also reduce the amount of noise produced by the sliding mechanism, and reduce frictional energy losses.

The details of one or more embodiments of the invention are set forth in the accompanying drawings and the description below. Other features, objects, and advantages of the invention will be apparent from the description and drawings, and from the claims.

### BRIEF DESCRIPTION OF DRAWINGS

FIG. 1 is a perspective view illustrating an exemplary cylinder-on-disc reciprocal movement friction testing machine.

FIG. 2 is a graph showing experimental coefficients of friction for exemplary materials.

### DETAILED DESCRIPTION

Sliding mechanisms are very common among mechanical devices, such as, for example, vehicular parts, particularly vehicular engine parts, machine tools and punches, saws, and material handling equipment. A sliding mechanism typically includes at least two sliding members that contact one another in a contact area. The contact area may be a point, a line, or an area on the surface of one of the members.

In one embodiment, this disclosure describes a sliding member with low friction coating including a hard carbon film, which is a thin film. The low friction coating is applied to any portion of the sliding member, and is preferably applied at a contact area where the sliding member contacts a second sliding member in a sliding mechanism. The second sliding member in the sliding mechanism may optionally have applied thereto in the contact area the low friction coating.

The hard carbon film in the low friction coating is typically a thin film including carbon. The thin film is preferably a crystalline hard carbon film selected from diamond and diamond-like carbon (DLC). The DLC thin film is made, or formed, from amorphous materials composed primarily of carbon atoms. The DLC materials include both mixed and amorphous sp³ and sp² bonds.

The diamond thin films may be deposited using, for example, chemical vapor deposition (CVD), and include a cubic crystal structure with an a₀ of 3.561 Å.

The DLC thin films include a-C (amorphous carbon), which consists only of carbon atoms, a-C:H (hydrogen amorphous carbon), which includes both hydrogen and carbon. The a-C and a-C:H materials may optionally include metal atoms such as, for example, titanium (Ti), molybdenum (Mo) and combinations thereof, and are generally referred to as MeC films.

In the a-C:H films, the amount of hydrogen is preferably less than or equal to 20% by mass, preferably less than or equal to 10 percent by mass, and more preferably less than or equal to 0.5 percent by mass.

The thickness of the low friction coating applied to the sliding member depends on the type or required performance of the sliding mechanism, the type of materials that the sliding members are made from, and the roughness of the surface of the sliding parts. Generally, the low friction coating is approximately 0.3 to 2.0 microns (μm) thick.

The surface roughness of low friction coating depends on the type or required performance of the sliding mechanism in question, the type of material (base material) that the sliding members are made from, and the roughness of the surface of the sliding parts. The surfaces of the sliding members, or the contact areas on the sliding members, are machined to a desired surface roughness before the low friction coating is applied. For example, if the sliding member is a part in an automobile engine, the member typically has an average surface roughness (Ra) of 0.5 μm or less, preferably 0.2 μm or less for aluminum alloy materials and 0.1 μm or less for iron alloy materials.

The low friction coatings may be applied to the sliding members by any conventional technique including, for example, chemical vapor deposition (CVD), physical vapor deposition (PVD), ion beam deposition, plasma assisted CVD, sputtering and the like.

As noted above, a lubricant may optionally be applied to a contact area between any of the sliding members in the sliding mechanism. The lubricant may vary widely depending on the intended application of the sliding mechanism, but preferred lubricants include greases derived from base oils selected from ester oils, ether oils, or a combination thereof. The preferred greases may also include other natural oils or synthetic oils such as mineral oil, silicone oil, and fluorocarbon oil.

The ester oil may be a natural oil or a synthetic oil, as long as it can be used as an ingredient for a lubricant. Some examples of the ester oil include ditridecyl glutarate, dioctyl adipate, diisodecyl adipate, ditridecyl adipate, dioctyl sebacate, trimethylolpropane caprylate, trimethylolpropane peralgonate, trimethylolpropane isostearynate, pentaerythritol2-ethylhexanoate, and pentaerythritol peralgonate. Trimethylolpropane caprylate is a preferred ester oil.

The ether oil may also be a natural oil or a synthetic oil, as long as it can be used as an ingredient for a lubricant. Some example of the ether oil include polyoxyalkylene glycol, dialkyldiphenyl ether, and polyphenyl ether. A preferred ether oil is dialkyldiphenyl ether.

The base oil used in the grease, which contains ingredients such as those described above, typically has a viscosity of approximately 2-100 millimeters squared per second (mm²/sec), preferably 2-40 mm²/sec, and more preferably 10-20 mm²/sec.

In addition, to provide improved wear resistance and enhanced resistance to evaporation, the kinetic viscosity of the base oil preferably remains above 2 mm²/sec. To provide enhanced performance at low temperatures, the kinetic viscosity of the base oil is preferably no more than 100 mm²/sec. Further, the viscosity index of the base oil is generally more than 100, specifically more than 120, and preferably more than 140. Selecting a base oil with a high viscosity index and excellent low viscosity properties may provide reduced oil consumption.

The grease may optionally include thickeners such as, for example, metallic and non-metallic soaps. Metallic soap materials may include sodium, calcium, aluminum, lithium, barium, copper, and lead salts of higher fatty acids. The salts may include higher fatty acids with lower fatty acids or with a dibasic acid, or some combination thereof. For these metallic soap materials, calcium stearate, lithium stearate, lithium hydroxy stearate, sodium stearate, and aluminum stearate are preferred materials. Furthermore, non-metallic soap materials include inorganic materials (organic thickeners) such as silicagel or bentonite, and organic materials (inorganic thickeners) such as copper phthalocyanine, allylurea, imidederivative, and Indanthrene-Blue. Other inorganic and organic materials may be used as non-metallic soap materials. For these non-metallic soap thickeners, urea compounds such as diurea, sodium terephthalamate, and polytetra fluoroethylene (PTFE) are preferred.

The grease may also include other components in addition to the base oil and thickeners described above. These other components may include antioxidants, cleaning agents, wear preventative agents, solid lubricants, and other types of elements. Antioxidants include, but are not limited to, those conventionally used in grease such as amine compounds, phenol, sulfur compounds, and carbamate. Cleaning agents include, but are not limited to, those conventionally used for grease such as sulfonate, phenate, salicylate, and amin compounds. Wear preventative agents include, but are not limited to, those conventionally used for grease such as phosphate ester, zinc alkyldithiophosphate, sulfer compounds, and chloride. Solid lubricants include, but are not limited to, those conventionally used for grease such as molybdenum disulfide, graphite, PTFE, and carbon Black.

Furthermore, the nature of the grease itself is influenced by the purpose for which the sliding mechanism is used and the operation status. Typically, the grease preferably has a grade of approximately 265 to 295 and a dropping point of 100° C. to 300° C.

The materials from which the sliding members are made include, but are not limited to, metallic materials typified by iron based alloys such as steel and nonferrous alloys such as aluminum alloy, resin materials typified by various types of rubbers and plastics, and ceramic materials. The sliding members may be made of the same material, or may be different materials.

The low friction sliding mechanism that includes the sliding members may be applicable to various kinds of sliding mechanisms for which grease is required under the conditions of relatively high temperature and high pressure. Although this application may be valuable in any particular type of machine or device, it is specifically used as a sliding mechanism in a vehicle such as an automobile. Some examples of a sliding mechanism in an automobile include a ball bearing and a sleeve where sliding occurs between metals, a seal ring and a drive shaft sliding where occurs between metal and rubber, and a bearing made from resin and a universal joint where sliding occurs which is the equivalent of sliding between metal and plastic.

### EXAMPLES

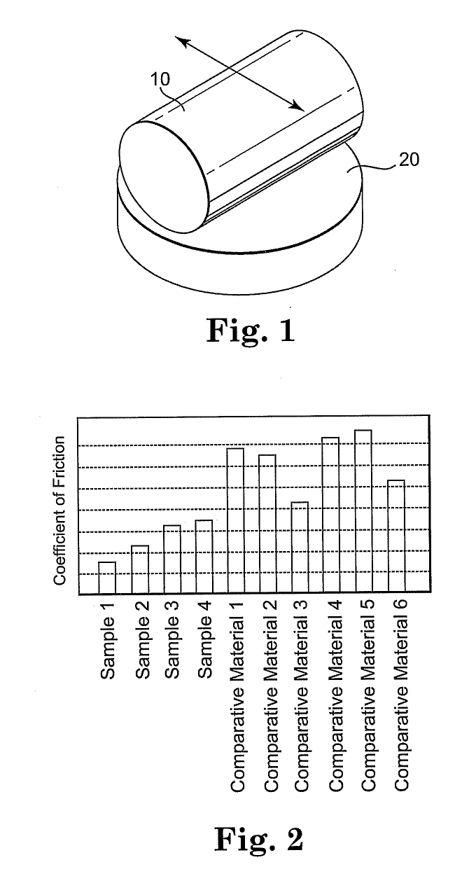

FIG. 1 is a perspective view of an exemplary Cylinder-On-Disc Single Reciprocal Movement Friction Testing Machine to measure the coefficient of friction at a contact area between sliding members in a sliding mechanism. As shown in the example of FIG. 1, a cylinder shaped test piece 10 and a disc shaped test piece 20 are created from SUJ2 steel. The cylinder shaped test piece 10 had a diameter of 15 mm and a length of 22 mm. Disc shaped test piece 20 had a diameter of 24 mm and a thickness of 7.9 mm.

A DLC a-C:H thin film with approximately 0.5% atomic percent of hydrogen by mass or less was added to test pieces 10 and 20. The DLC thin film, which had a Knoop hardness of HK=2170 kg/mm², maximum surface roughness (Ry) of 0.03 μm, and thickness of 0.5 μm, was formed on the surface of the upper sliding part of the disc shaped test piece 20 by a PVD Arc Ion Type Plating method to create disc shaped test piece 20. The resulting cylinder shaped test piece 10 and the disc shaped test piece 20 created the exemplary sliding mechanism.

Approximately 0.3 g of the grease shown in Table 1 below was applied at the contact area between the cylinder shaped test piece 10 and the disc shaped test piece 20. Pieces 10 and 20 were created differently, as also shown in Table 1, where the corresponding grease was applied to each piece.

A load of 100 Newtons (N) was applied between pieces 10 and 20, where piece 10 moved an amplitude of 1.5 mm at a frequency of 50 Hz. Each testing period lasted 10 minutes in a temperature of 80° C.

A friction test was conducted to measure the coefficients of friction for each sample, and the coefficients of friction of the sliding mechanism were tested 10 minutes after the start of testing each sample are shown in the plot of FIG. 2. FIG. 2 does not include numerical values of each coefficient of friction, but provides exemplary comparisons between the coefficients of friction measured for samples 1-4 Comparative Materials 1 to 6 do not include a DLC coating material or other hard carbon film.

The results shown in FIG. 2 indicate that a hard carbon film reduces the coefficient of friction when compared to non-hard carbon film coated materials. Excluding cases in which a DLC thin film was not formed on the disc shaped test piece, the same operations of samples 1 to 4 were repeated and the coefficients of friction were measured. The obtained results are also shown in FIG. 2.

TABLE 1

| | | Cylinder | | |
|---|---|---|---|---|
| | Disc shaped | shaped | | |
| | test piece | test piece | Grease | |
| | material | material | Base Oil | Thickener |
| Sample 1 | DLC Coating | SUJ2 | Ester | Li Stearate |
| | Material*¹ | | | |
| Sample 2 | DLC Coating | SUJ2 | Ester | Li Stearate |
| | Material*¹ | | | |
| Sample 3 | DLC Coating | SUJ2 | Ester | Diurea |
| | Material*¹ | | | |
| Sample 4 | DLC Coating | SUJ2 | Ester | Diurea |
| | Material*¹ | | | |
| Comparative | SUJ2 | SUJ2 | Ester | Li Stearate |
| Material 1 | | | | |
| Comparative | SUJ2 | SUJ2 | Ester | Li Stearate |
| Material 2 | | | | |
| Comparative | SUJ2 | SUJ2 | Mineral Oil | Li Stearate |
| Material 3 | | | | |
| Comparative | SUJ2 | SUJ2 | Ester | Diurea |
| Material 4 | | | | |
| Comparative | SUJ2 | SUJ2 | Ester | Diurea |
| Material 5 | | | | |
| Comparative | SUJ2 | SUJ2 | Mineral Oil | Diurea |
| Material 6 | | | | |

Table 1 describes the materials and greases used to generate the coefficient of friction data displayed in FIG. 2. All greases used in Table 1 include the same additives including of an antioxidant, a cleaning agent, a wear preventative agent, and a solid lubrication oil. The asterisk indicates that the surface of the upper sliding part of a disc shaped test piece 20 is made from SUJ2 alloy on which a DLC thin film is coated.

Various implementations and embodiments of the invention have been described. Nevertheless, it is understood that various modifications can be made without departing form the invention. These and other embodiments are within the scope of the following claims.

1. A sliding mechanism comprising:
a contact area between at least two sliding members;
a low friction coating on at least a portion of one of the at least two sliding members at the contact area, wherein the low friction coating is a hard carbon film; and
a grease on the low friction coating, wherein the grease comprises a base oil selected from the group consisting of ester oils, ether oils and combinations thereof.

2. The sliding mechanism of claim 1, wherein the hard carbon having a diamond like carbon material selected from the group consisting of diamond, amorphous a-C diamond like carbon (DLC), and amorphous a-C:H DLC.

3. The sliding mechanism of claim 1, wherein the low friction coating film comprises a-C:H.

4. The sliding mechanism of claim 2, wherein the a-C:H in the hard carbon film comprises less than or equal to 20% by mass H.

5. The sliding mechanism of claim 2, wherein the a-C:H in the hard carbon film comprises less than or equal to 10% by mass H.

6. The sliding mechanism of claim 2, wherein the a-C:H in the hard carbon film comprises less than 0.5% by mass H.

7. The sliding mechanism of claim 1, wherein the hard carbon film further comprises a metal selected from the group consisting of Ti and Mo and combinations thereof.

8. The sliding mechanism of claim 1, wherein the grease further comprises a metallic soap selected from the group consisting of calcium compounds, lithium compounds, urea compounds and combinations thereof.

9. A method comprising:
forming a low friction coating on at least a portion of a sliding member, wherein the low friction coating is a hard carbon film comprising a diamond like carbon material selected from the group consisting of diamond, amorphous a-C diamond like carbon (DLC), and amorphous a-C:H DLC; and
adding a grease on the low friction coating, wherein the grease comprises a base oil selected from the group consisting of ester oils, ether oils and combinations thereof.

10. The method of claim 9, wherein the low friction coating film comprises a-C:H.

11. The method of claim 9, wherein the a-C:H in the hard carbon film comprises less than or equal to 20% by mass H.

12. The method of claim 9, wherein the a-C:H in the hard carbon film comprises less than or equal to 10% by mass H.

13. The method of claim 9, wherein the a-C:H in the hard carbon film comprises less than 0.5% by mass H.

14. The method of claim 9, wherein the hard carbon film further comprises a metal selected from the group consisting of Ti and Mo and combinations thereof.

15. The method of claim 9, wherein the grease further comprises a metallic soap selected from the group consisting of calcium compounds, lithium compounds, urea compounds and combinations thereof.

16. A sliding member comprising a low friction coating on at least a portion thereof, wherein the low friction coating is a hard carbon film comprising an amorphous a-C:H diamond-like carbon, wherein the a-C:H in the hard carbon film comprises less than or equal to 20% by mass H.

17. The sliding member of claim 16, wherein the member further comprises a lubricant on the hard carbon film, the lubricant comprising a grease derived from a base oil selected from the group consisting of ester oils, ether oils and combinations thereof.

18. The sliding member of claim 17, wherein the hard carbon film further comprises a metal selected from the group consisting of Ti and Mo and combinations thereof.

19. The sliding mechanism of claim 17, wherein the grease further comprises a metallic soap comprising at least one of calcium, lithium, or urea compounds.

20. A sliding mechanism comprising at least two sliding members, wherein the sliding members comprise friction reducing means, the friction reducing means comprising a combination of a diamond like carbon film and a grease comprising at least one of an ester or an ether base oil.

21. A movement structure comprising:
at least two sliding members;
a hard carbon film on at least a portion of one of the at least two sliding members, wherein hard carbon film comprises less than or equal to 20% by mass H; and
a grease on the hard carbon film, wherein the grease comprises a base oil selected from the group consisting of ester oils, ether oils and combinations thereof.
